(19) United States
(12) Patent Application Publication
(10) Pub. No.: US 2026/0134920 A1
(43) Pub. Date: May 14, 2026

(54) ALL LEVELS PROGRAMMING WITH LOOP DEPENDENT PILLAR BOOSTING

(71) Applicant: Micron Technology, Inc., Boise, ID (US)

(72) Inventors: Huai-Yuan Tseng, San Ramon, CA (US); Jeffrey S. McNeil, Nampa, ID (US); Sheyang Ning, San Jose, CA (US); Lawrence Celso Miranda, San Jose, CA (US); Tomoko Ogura Iwasaki, San Jose, CA (US); Akira Goda, Tokyo (JP)

(73) Assignee: Micron Technology, Inc., Boise, ID (US)

(21) Appl. No.: 19/379,736

(22) Filed: Nov. 4, 2025

Related U.S. Application Data
(60) Provisional application No. 63/718,864, filed on Nov. 11, 2024.

(51) Int. Cl. G11C 16/10; G11C 16/04; G11C 16/08; G11C 16/24

(52) U.S. Cl. CPC G11C 16/10; G11C 16/0483; G11C 16/08; G11C 16/24

(57) ABSTRACT

A method performed by a memory device to perform all levels programming with loop dependent pillar boosting is provided. The method comprises, in at least one loop of a plurality of operational loops performed by a memory controller, causing a first bias voltage to be applied to a plurality of word lines and a target bit line. The method further comprises causing a set of ramping voltages to be applied to the plurality of word lines over a plurality of ramp-up periods. Each ramping voltage of the set of ramping voltages is incremented by a delta voltage in a corresponding ramp-up period of the plurality of ramp-up period. The method further comprises identifying a target ramp-up period for the target memory cell. The method further comprises, during the identified target ramp-up period, causing a second bias voltage to be applied to the target bit line.

### RELATED APPLICATIONS

This application claims priority to U.S. Provisional Application No. 63/718,864 filed on Nov. 11, 2024, titled “ALL LEVELS PROGRAMMING WITH LOOP DEPENDENT PILLAR BOOSTING.” The contents of U.S. Provisional Application No. 63/718,864 are incorporated by references herein in their entirety for all purposes.

### TECHNICAL FIELD

This disclosure relates to one or more systems for memory, including techniques for all levels programming with loop dependent pillar boosting.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIGS. 4A-4B illustrate a portion of a three-dimensional structure of memory cell string having a pillar, in accordance with examples as disclosed herein.

FIG. 5 illustrates a set of pillars corresponding to multiple programming levels in a memory array in accordance with examples as disclosed herein.

FIG. 6 illustrates the trends of program voltages, pillar potentials and effective programming voltages across loops under an All-levels Programming (ALP) approach in accordance with examples as disclosed herein.

FIG. 7 illustrates the trends of program voltages, pillar potentials and effective program voltages across loops under a revised ALP approach in accordance with examples as disclosed herein.

FIGS. 8A-8C are charts showing waveforms of word line and bit line bias voltages applied to different pillars and the resulting pillar potentials in an ALP operation in accordance with examples as disclosed herein.

FIG. 9 is a flowchart illustrating a method for performing All-levels Programming with loop dependent pillar boosting in accordance with examples as disclosed herein.

### DETAILED DESCRIPTION

Memory cells of a memory devices may have multiple logical levels. For instance, an MLC cell has 4 levels; a TLC cell has 8 levels; and a QLC cell has 16 levels. Memory cells with multiple logical levels are typically programmed one logic level at a time using a method referred to as Incremental Step Pulse Programming (ISPP). The ISPP method tends use multiple programming loops to program the multiple levels of memory cells and therefore has slower programming speed and low efficiency. All-Levels Programming (ALP) enhances the programming speed and efficiency of memory devices (e.g., a NAND device) by allowing simultaneous programming of all levels of memory cells in a memory array, unlike ISPP. By reducing the number of programming loops, ALP accelerates the programming process, making it a more efficient method for programming high-density memory arrays compared to ISPP.

However, ALP may have certain limitations. The reduced number of programming loops may result in a larger step increase in the threshold voltage (ΔVt) of the target memory cell between loops, leading to greater noise and reduced precision during programming. Additionally, memory cells programmed with ALP generally exhibit a lower Read Window Budget (RWB) compared to those programmed with ISPP, which also negatively affects device performance. A RWB refers to the voltage gap between the threshold voltage distribution of two adjacent logic levels. If the voltage gap is large (or the threshold voltage distribution is narrow), the RWB is large, which means that it is easier for the reading operation to distinguish between two adjacent logic levels.

The present disclosure introduces various improved ALP approaches that address these potential drawbacks. Under the improved ALP approaches, certain parameters of word line and bit line waveforms, such as step-increase of bias levels and timing, can be adjusted for different programming levels and across different programming loops. These novel approaches generate variable pillar potential values across programming loops, and improve the RWB while further enhancing programming speed and efficiency in the memory device.

In one embodiment, while the bias voltage applied to word lines is incrementally ramped up in multiple “staircases”, different delta voltages (i.e., the voltage increments between the steps) may be applied across successive programming loops. For example, a smaller delta voltage can be applied during the first loop, followed by a larger delta voltage in the second loop, and an even larger delta voltage in the subsequent loops. The variation in delta voltages across programming loops results in corresponding variations in pillar potentials, thereby altering the effective program voltage applied to the target memory cell during each loop. As a result, the RWB of the programmed memory cells can be improved.

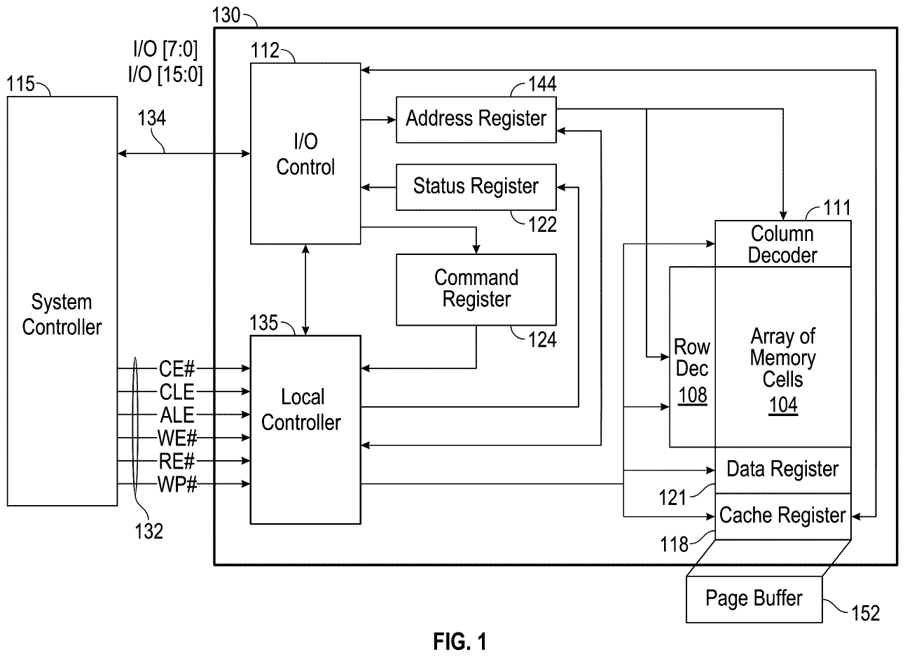

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

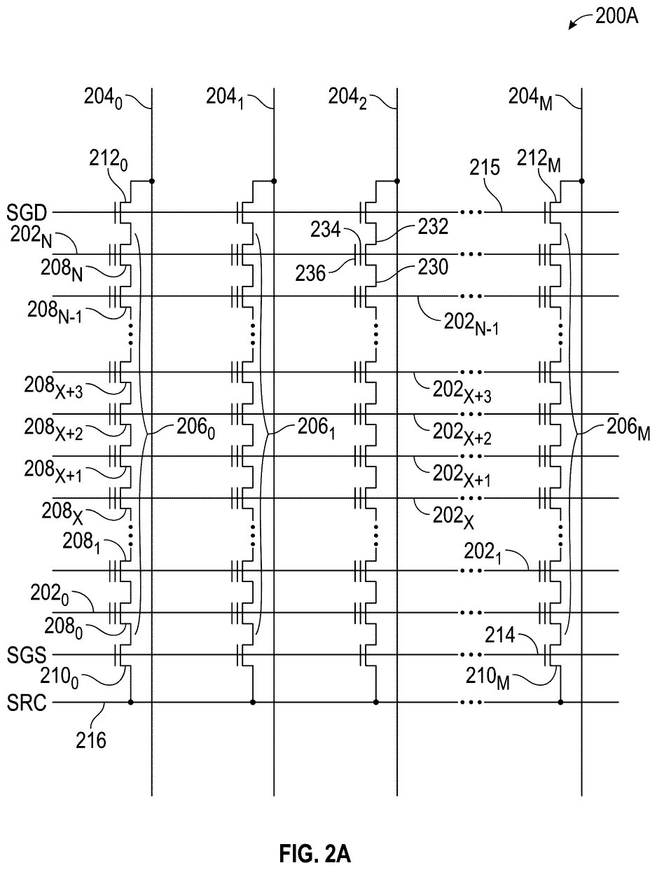

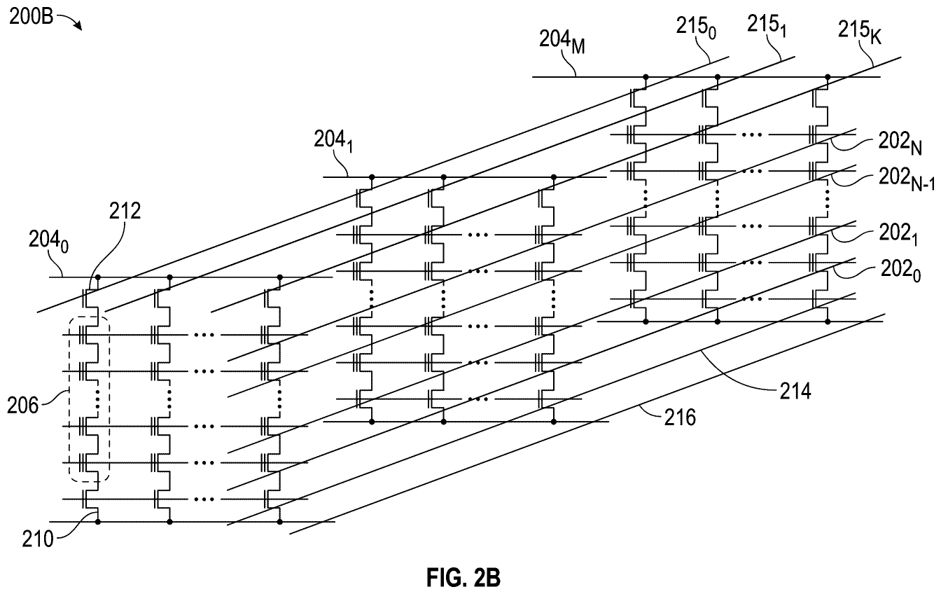

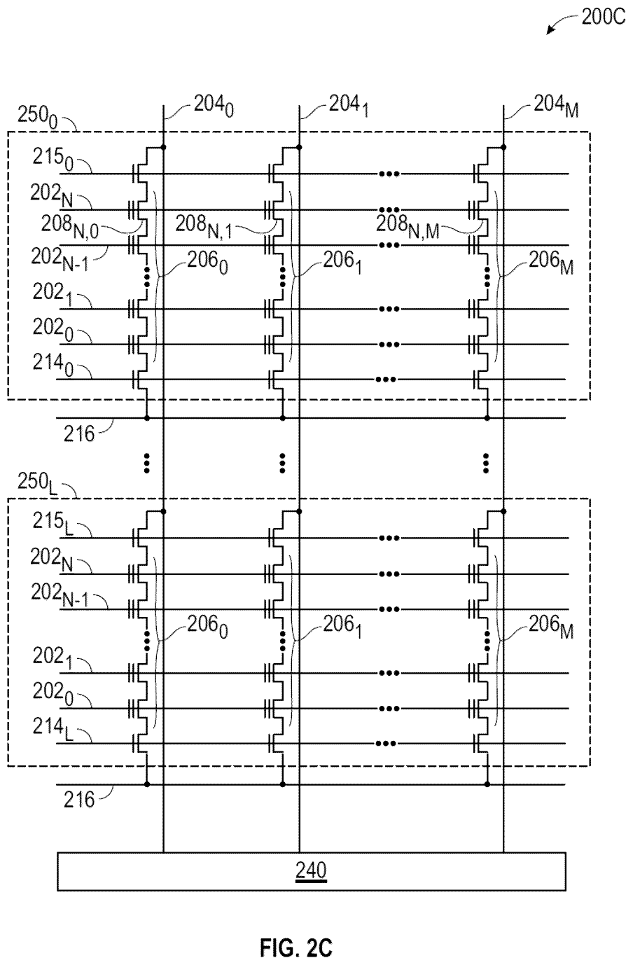

FIG. 2A-2B are example schematics of portions of an array of memory cells 200A, such as a NAND memory array. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

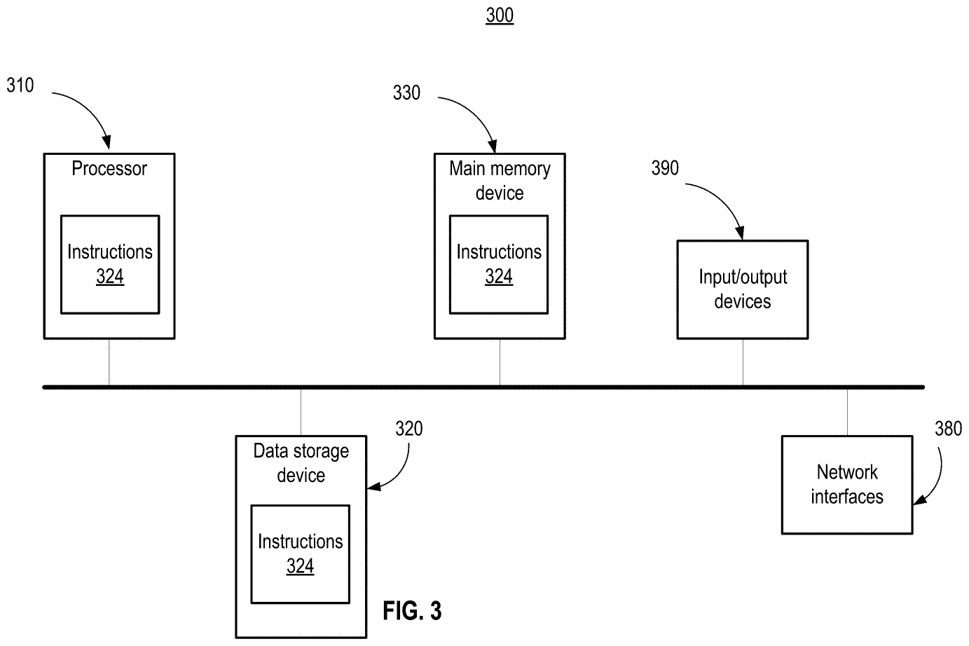

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of FIGS. 1-9, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-9 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-9. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

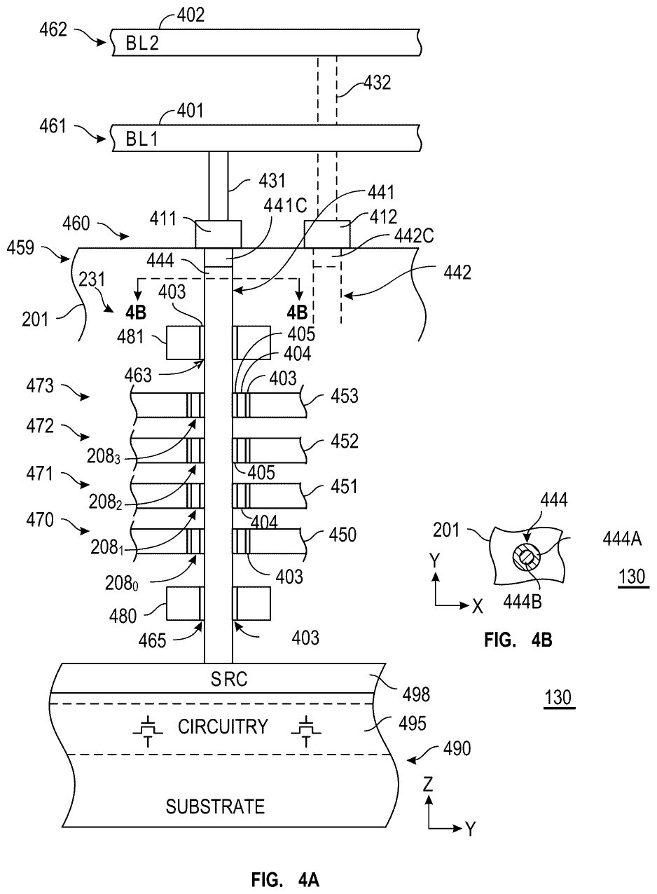

FIG. 4A-F IG. 4B shows a side view (e.g., a cross section with respect to the X-Z directions) of a portion of the three-dimensional structure of memory device 130 including a structure of memory cell string 231 (e.g., a NAND string) having a pillar 441, according to some embodiments described herein. FIG. 4A shows the structure of one memory cell string (e.g., memory cell string 231) of memory device 130. However, other memory cell strings (e.g., NAND strings 206₀-206_{M} in FIG. 2A and NAND strings 206 in FIG. 2B) can have a similar or the same structure as memory cell string 231 shown in FIG. 4A.

Starting from the top of FIG. 4A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIGS. 4A-4B shows directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 4A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 4A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 4A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 4A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 4A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 4A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 4A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 4A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 comprises multiple memory cell strings (one of which is shown as memory cell string 231).

As shown in FIG. 4A, pillar (e.g., a vertical pillar) 441 can be a part of memory cell string 231 and can have a length extending in the Z-direction (e.g., extend vertically with respect to substrate 490). Pillar 441 can extend through memory cells 208₀, 208₁, 208₂, and 208₃ of memory cell string 231. Pillar 441 can include (e.g., can be formed from) a conductive material (e.g., conductively doped polysilicon). Each of memory cells 208₀, 208₁, 208₂, and 208₃ can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 4A only shows four memory cells 208₀-208_{3,} memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 4A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 4A, memory cells 208₀, 208₁, 208₂, and 208₃ of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 4A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 4A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for examples, word lines or control gates. Access lines 450, 451, 452, and 453 can include (e.g., can be formed from) a conductive material (or materials). Example materials for access lines 450, 451, 452, and 453 include metal, alloy, doped polysilicon, other conductive materials.

In FIG. 4A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 4A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 4A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory cell. As shown in FIG. 4A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a floating gate (e.g., to store charge) in a memory cell (e.g., a memory cell 208₀, 208₁, 208₂, and 208₃). In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 4A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 4B. FIG. 4B shows a top view (e.g., a cross section with respect to the X-Y plan) of portion 444 of pillar 441 along line 4B-4B of FIG. 4A. As shown in FIG. 4B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

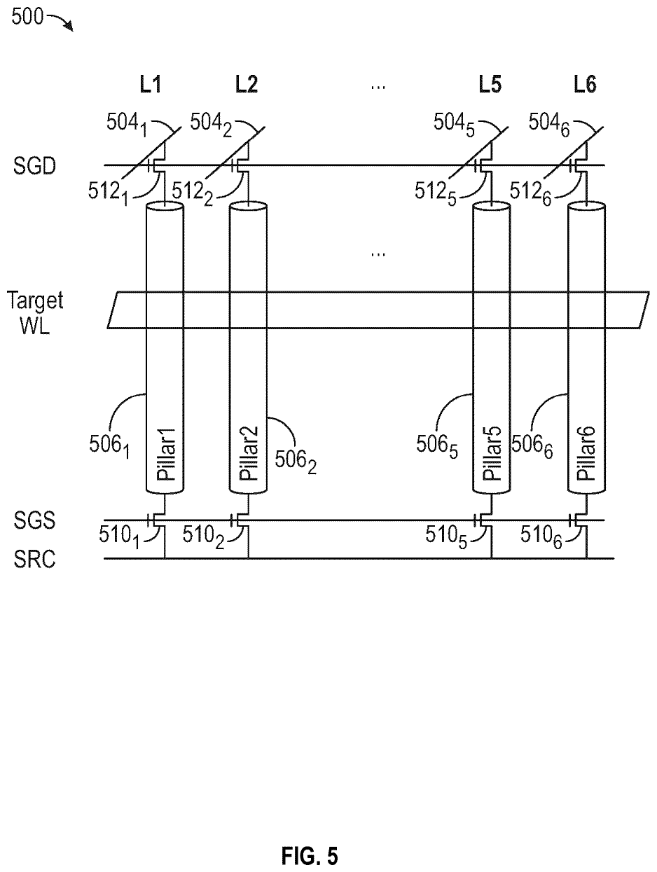

FIG. 5 illustrates a set of pillars corresponding to multiple programming levels in a memory array in accordance with examples as disclosed herein. Memory array 500 forms, for example, a part of a TLC memory device. As described above, a TLC device has 8 logic levels (denoted as L0-L7). The below description uses TLC device as an example. It is understood that the technologies described can be applied to other types of memory devices like a QLC device. Memory array 500 is arranged in rows, each corresponding to a word line, and columns, each corresponding to a bit line. A memory cell is located at the intersection of a word line and a bit line. Similar to memory array 200A shown in FIG. 2A, memory array 500 includes a series of word lines. However, for clarity, only a target word line is shown in FIG. 5. In this disclosure, the memory cell that is the target of a specific memory access operation is sometimes referred to as the “target memory cell” or “selected memory cell”. The word line associated with a selected memory cell is referred to as the “target word line” or “selected word line”. The other word lines are referred to as the “unselected word lines”. The bit line associated with the selected memory cell is referred to as the “target bit line”.

Memory array 500 includes a series of bit lines (504₁, 504₂, . . . , 504₆), each corresponding to different programming levels (L1, . . . L6). For simplicity, bit lines corresponding to programming levels L0 and L7 are omitted. Each bit line is electrically connected to a drain-side select transistor, also known as a drain select gate (SGD), such as transistor 463 controlled by select line 481 in FIG. 4A, or SGD transistors 512₁, 512₂, ..., 512₆ in FIG. 5. An SGD transistor connects to a string of series-connected TLC memory cells, which are then connected to a source-side select transistor, also known as a source select gate (SGS), such as transistor 465 controlled by select line 480 in FIG. 4A, or SGS transistors 510₁, 510₂, . . . , 510₆ in FIG. 5. Each SGS transistor is connected to a common source (SRC).

As illustrated in FIG. 5, memory array 500 includes a set of vertical pillars (e.g., Pillar1 (506₁), Pillar2 (506₂), . . . , Pillar6 (506₆)), each representing the substrate or channel region of a vertical string of series-connected memory cells. These pillars are substantially the same or similar to pillars 441 and 442 shown in FIG. 4A. In one embodiment, the pillars represent the channel regions of the access transistors of a vertical string of memory cells. The channel region may be composed of polysilicon or other suitable materials. In FIG. 5, Pillar1 corresponds to channel region of the string of memory cells programmed to the L1 logical level, Pillar2 to the L2 level, and so on, up to Pillar6. It should be noted that although the pillars in FIG. 5 are arranged in ascending order of programmed states, this is presented for illustrative purposes only. In practical implementations, the pillars within a memory array may correspond to any programming state and in any order.

Memory access operations (e.g., a program operation, an erase operation, etc.) can be performed on memory cells by applying particular bias voltages to the word lines connected to those cells. During a program operation, a selected memory cell is programmed to a target level by applying a series of program voltages to the selected and/or the unselected word lines. There are at least two approaches for programming a selected memory cell to a target level. One approach is Incremental Step Pulse Programming (ISPP). The other approach is All-levels Programming (ALP).

In the ISPP approach, a word line driver applies a series of high-amplitude pulses of voltage levels to the selected word lines. Each pulse in the series increases by a predefined step height, such as 0.33V. These pulses can be applied by the word line driver iteratively, with each iteration referred to as a “loop”. As the bias voltage on the selected word lines increases after each loop, the charge stored on the charge storage structure (e.g., material 404 illustrated in FIG. 4A) of the selected memory cell gradually increases. As a result, the voltage level of the selected memory cells on the selected word lines can be gradually raised to the required level for the memory access operation.

In ISPP, the steps required for programming different levels, e.g., L1 and L5, differ because each level corresponds to a distinct charge state. Higher levels require more charge to be stored in the memory cell compared to lower levels. For this reason, in ISPP programming, memory cells of different programming levels are not programmed together. For example, consider the target memory cells on Pillar1 506₁ and Pillar5 506₅ in FIG. 5. If the same incrementing bias voltage of the target word line is applied to both Pillar1 and Pillar5, the target memory cell on Pillar1 may reach its target level sooner, while the target memory cell on Pillar5 may still need additional incremental voltages. In this situation, continuing to apply higher voltages on the target word line could cause program error on Pillar1. Thus, in ISPP, memory cells of different levels are programmed separately in different programming loops.

In the ALP approach, rather than separately programming different levels of memory cells in a memory array, each program pulse programs all levels of memory cells simultaneously. In some embodiments, ALP includes two phases. In the first phase, a series of incrementally increasing word line voltages is applied to a set of word lines of a memory array. During the first phase, respective pillars corresponding to various program levels are floated. When a pillar is floated, it is electrically isolated from the voltage supply and the ground. In one embodiment, a set of pillars corresponding to different program levels are floated in sequence. For example, a pillar corresponding to L1 is floated first, a pillar corresponding to L2 is floated second, and so on.

A pillar can be floated by the memory controller turning both the select gate drain (SGD) and select gate source (SGS) transistors off. For example, to float Pillar1, the control gate of transistor 512₁ is toggled from a high voltage level to approximately 0V to turn off transistor 512₁ (e.g., if transistor 512₁ is an NMOS transistor), thereby preventing the corresponding bit line 504₁ from discharging to Pillar1. Meanwhile, bit line 504₁ is toggled from approximately 0V to a high voltage level such that Pillar1 remains floating during the remainder of the first phase.

Once a pillar is floated, the voltage level of each pillar (sometimes referred to as “pillar potentials”) can be boosted due to the step-increase of the bias voltage applied to the word lines. The pillar voltage can be boosted via, for example, capacitive coupling between the gate and channel region (pillar) of the memory cell transistors. By the end of the first phase, the pillar potentials of different pillars are boosted to different voltage levels. In one embodiment, pillar potential for programming level L1 (Pillar1) is boosted to a highest value, pillar potential for programming level L2 (Pillar2) is boosted to a next highest value, and pillar potential for programming level L6 (Pillar6) is boosted to a lowest value. In some embodiments, pillar potential for the highest programming level, such as L7 in a TLC device, is not boosted and remains at 0V.

In the second phase of the ALP, a programming pulse (Vpgm) is applied to the target word line to program the target memory cells. Because the pillar potentials of different pillars have already been boosted to different levels in the first phase, in the second phase, a same programming voltage can be simultaneously applied to all the pillars to program the target memory cells. The ALP operation, which includes both the first and the second phases, can be repeated iteratively by the memory controller until target levels of the target memory cells have been programmed and verified. Similar to ISPP, each iteration in ALP is also called a “loop”.

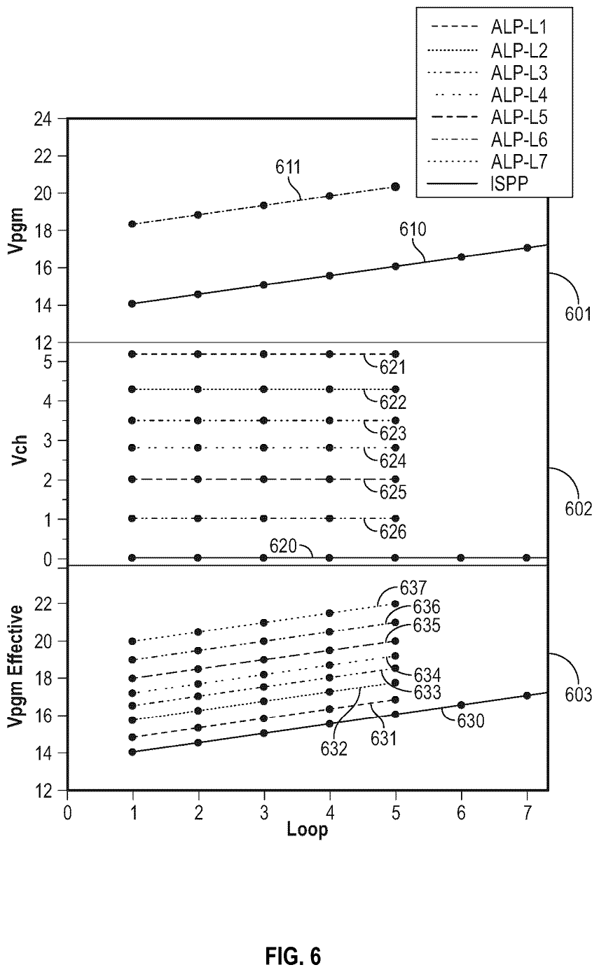

FIG. 6 illustrates the trends of program voltages, pillar potentials, and effective programming voltages across multiple loops under an All-levels Programming (ALP) approach in accordance with examples as disclosed herein. FIG. 6 includes three sub-figures, all sharing the same horizontal axis. The horizontal axis represents the loops performed by a memory controller during a memory access operation (e.g., a program operation).

In the top sub-figure, the vertical axis represents Vpgm, which is the program voltage applied to a target memory cell during a program operation. Each data point shows the specific Vpgm applied to the target memory cell during that loop. In the ISPP approach (reference 610), Vpgm steps up incrementally from a lower starting point (e.g., 14V) to an endpoint (e.g., 20V, not shown because of the limited horizontal scale). In the ALP approach (reference 611), Vpgm steps up incrementally from a higher starting point (e.g., 18V) than the ISPP approach, but reaches a same or similar endpoint as in the ISPP approach.

In the middle sub-figure, the vertical axis represents the pillar potential (Vch) of the pillar where the target memory cell is located. In ISPP, the pillar potential remains at 0V (reference 620) for all programming levels. In ALP, instead of staying constant during all the loops, the pillar potential varies based on the programming level, with L1 pillars having the highest potential (reference 621) at approximately 5V. Pillar potentials of other levels—L2 (reference 622), L3 (reference 623), L4 (reference 624), L5 (reference 625), and L6(reference 626)—remain at a constant value during all loops, but the value decreases as the programming levels increase. As shown in the sub-figure, pillar potential for L6 remains at a constant value of around 1V. The pillar potential for L7 pillars remains at 0V and is not shown.

In the bottom sub-figure, the vertical axis represents the effective program voltage (Veff) applied to the target memory cell, calculated as Vpgm minus Vch. In ISPP (reference 630), Veff is the same as Vpgm (reference 610) because Vch is 0V. In ALP, Veff of each programming level increases linearly across each loop. The value of Veff depends on the pillar's programming level. For example, L7 (reference 637) exhibits the highest effective voltage, while L1 (reference 631) has the lowest. Due to these variations in Veff across programming different levels, ALP can achieve the same programming effect with fewer loops compared to ISPP. For example, while ISPP may require 20 loops to program a memory cell, ALP can achieve the same result in just 5 loops. As a result, the programing time under the ALP approach is reduced.

It should be noted that the number of loops and the values of Vpgm, Vch, and Veff shown in FIG. 6 are for illustrative purposes only. There can be different number of loops in ISPP and/or ALP approaches and the voltage values in each loop can be different.

However, because ALP uses fewer loops, the step-increase in threshold voltage (ΔVt) of the target memory cell between loops is larger than the delta Vt of the target memory cells in ISPP. Large delta Vt results in greater noise during programming with ALP than ISPP. In addition, memory cells programmed under ALP typically may have a lower Read Window Budget (RWB), compared to those programmed under ISPP. In one example, while the RWB of memory cells programmed with ISPP may be around 2.0V, the RWB of memory cells programed with ALP may be around 1.8V. To address this problem, a revised ALP approach is introduced herein.

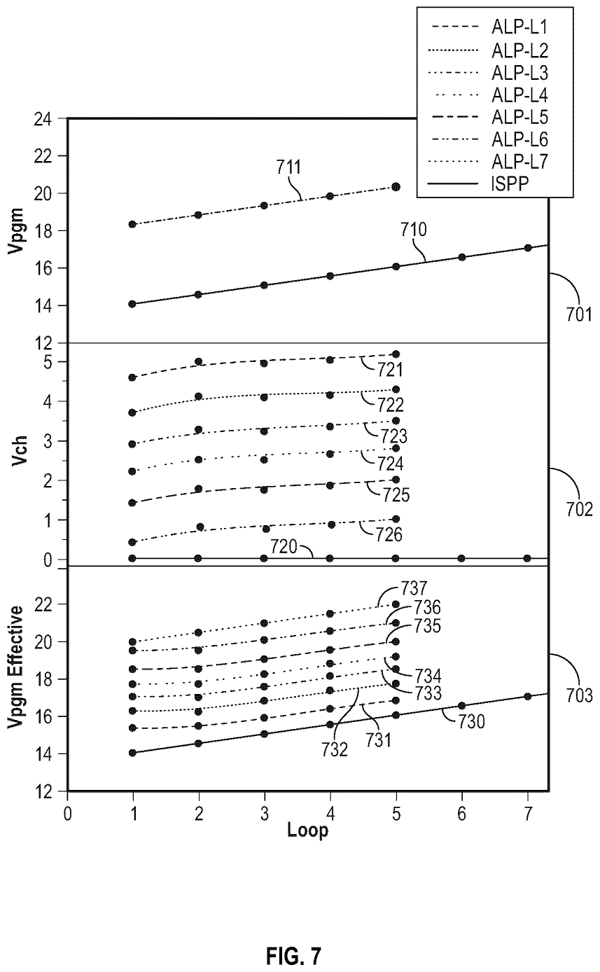

FIG. 7 illustrates the trends of program voltages, pillar potentials and effective program voltages across loops under a revised ALP approach in accordance with examples as disclosed herein. The horizonal and vertical axes in FIG. 7 are the same as those in FIG. 6. FIG. 7 includes three sub-figures. The top-subfigure, which is the same as the top-subfigure in FIG. 6, shows program voltages (Vpgm) applied to a target memory cell across different loops.

In the middle sub-figure, the pillar potentials of different programming levels in FIG. 7 are adjusted to have different values in each loop, unlike in FIG. 6 where they remain constant. For example, in the L2 pillar (reference 722), the pillar potential starts from a lower initial point in loop 1 (compared to the constant pillar potential value in reference 621 of FIG. 6). In subsequent loops, the L2 pillar potential rises in loop 2, decreases in loop 3, and then gradually increases until loop 5. Other pillars—L1 (reference 721), L3 (reference 723), L4 (reference 724), L5 (reference 725), and L6 (reference 726)—show similar trends. The pillar potential for L7 remains at 0V and is not shown.

The bottom sub-figure shows the effective program voltages (Veff), calculated as Vpgm minus Vch, applied to the target memory cells. Since the pillar potentials change in each loop (as seen in the middle sub-figure), the effective program voltages also vary accordingly. For example, in the L2 pillar (reference 732), Veff starts from a higher value in loop 1, decreases in loop 2, and then gradually increases until loop 5. Similar trends are observed for the other pillars—L1 (reference 731), L3 (reference 733), L4 (reference 734), L5 (reference 735), and L6 (reference 736). The effective voltage for L7 (reference 737) continues to increase linearly since its pillar potential is not adjusted.

Compared to the ALP approach shown in FIG. 6, the revised ALP approach in FIG. 7 improves the RWB of the programmed memory cells by adjusting the pillar potentials for different programming levels in different loops. The pillar potentials can be adjusted by adjusting the word line voltage and/or the bit line voltages, as described in detail below. In one example, the RWB of memory cells programmed under the revised ALP approach is around 2.2V, which is 0.4V higher than the 1.8V RWB in the ALP approach shown in FIG. 6. The figures below illustrate an implementation for adjusting the pillar potentials for different programming levels.

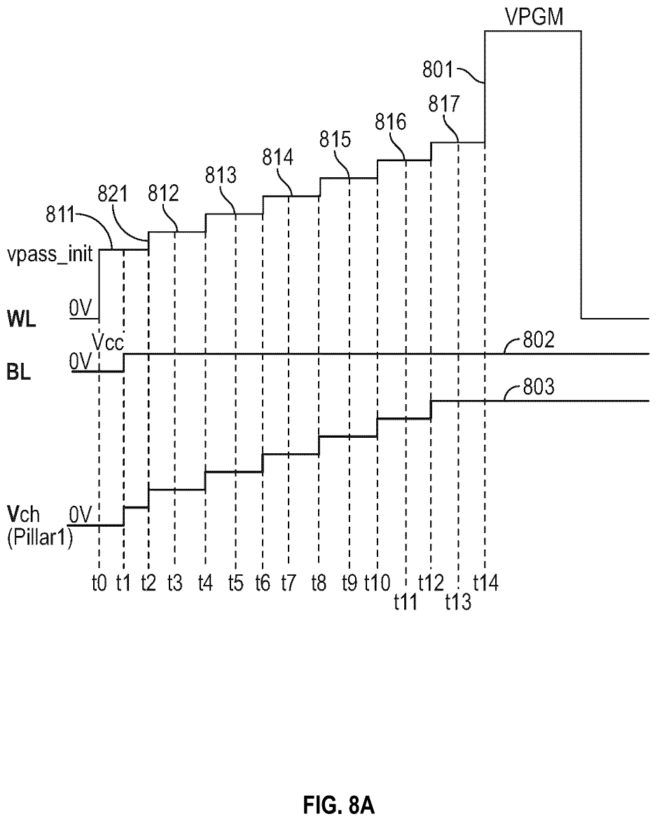

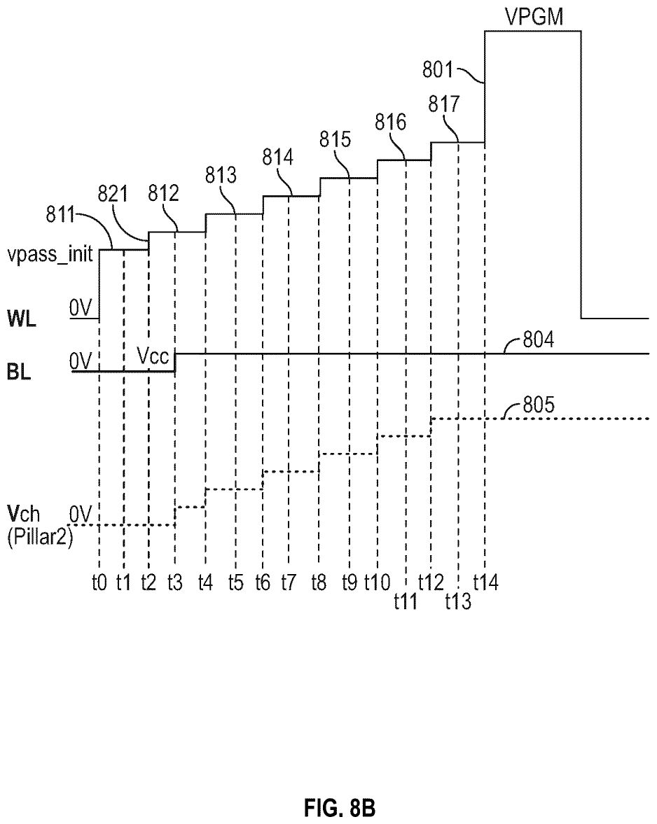

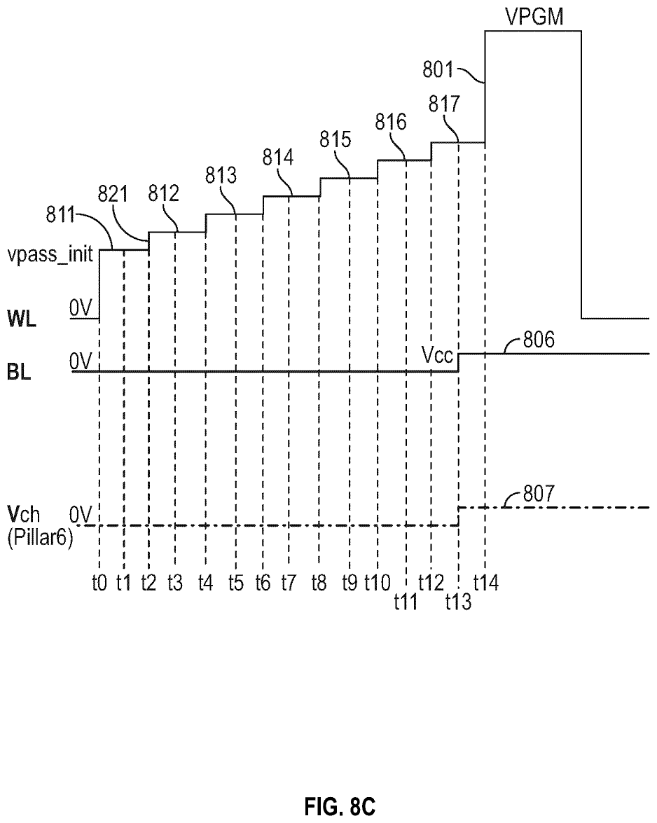

FIGS. 8A-8C are charts showing waveforms of word line and bit line bias voltages applied to different pillars and the resulting pillar potentials in an ALP operation in accordance with examples as disclosed herein. In these figures, the horizontal direction represents time within a loop of an ALP operation. In one embodiment, the time period before t₁₄ represents the first phase of the ALP operation, and the time period after t₁₄ represents the second phase of the ALP operation. In the vertical direction, the voltages shown in the three waveforms are not to scale. The top waveform (“WL”) shows bias voltages applied to word lines in memory array 500 in FIG. 5, including both the selected word line (where the target memory cell is located) and the unselected word lines (other word lines in memory array 500). The middle waveform (“BL”) shows voltages applied to the target bit line. The bottom waveform (“Vch”) shows waveforms of pillar potential of the pillar where the target memory cell is located. Unlike the WL and BL waveforms which show voltages applied by the memory controller, the Vch waveform shows the effect on pillar potential as a result of applying the bias voltages to word line and bit lines. Referring back to FIG. 5, the Vch waveform in FIG. 8A shows waveform in pillar potentials of L1 (Pillar1), the Vch waveform in FIG. 8B shows waveform in pillar potentials of L2 (Pillar2), and the Vch waveform in FIG. 8C shows waveform in pillar potentials of L6 (Pillar6).

As previously explained, during the first phase of an ALP operation, the pillars corresponding to the programming level are floated, and their pillar potentials are boosted as bias voltages on the word lines increase incrementally. FIG. 8A illustrates the timing and magnitude of bias voltages applied to the word lines and target bit line that result in the pillar potential boost for Pillar1. In one example, the bias voltage applied to word lines (WL) is ramped up incrementally in multiple “staircases”. The first staircase is at level 811 between t₀ and t₂. The second staircase is at level 812 between t₂ and t₄. The third staircase is at level 813 between time t₄ and t₆, and so on, with the last staircase being at level 817 between t₁₂ and t₁₄.

At time t₀, the ALP operation enters the first phase. The bias voltage applied to word lines ramps up from 0V to Vpass_init (level 811). Vpass_init is applied to both the selected word line (e.g., Target WL in FIG. 5 or word line associated with memory cell 472, assuming memory cell 472 is the target memory cell) and the unselected word lines (e.g., word lines associated with memory cells 470, 471, and 473 in FIG. 4A). The amplitude of Vpass_init is high enough to turn on all memory cells on Pillar1. Also at time t₀, the bias voltage applied to the target bit line 504₁ is at 0V. In one embodiment, the bias voltage applied to SGD is at a high voltage level (not shown) and consequently, the SGD transistor 512₁ is turned on prior to ramping-up the WL staircases. The pillar potential of Pillar1 is level-set by bit line 504₁ to be at 0V.

At time t₁, which is during the ramp-up time of the first staircase, voltage applied to target bit line 504₁ is raised from 0V to a high voltage level (e.g., Vcc at level 802). This rise turns off transistor 512₁ (because the gate-source voltage of the transistor 512₁ is less than the threshold voltage) and causes Pillar1 to float. After Pillar1 is floated, its pillar potential Vch is gradually boosted by subsequent WL staircases, e.g., at times t₂, t₄, etc., until it reaches a final boosted level 803 during the last WL staircase between time t₁₂ and t₁₄. As described above, such a pillar potential boost can be due to capacitive coupling between the gate of the transistors 512 and the pillar.

At time t₁₄, the ALP operation enters the second phase. The bias voltage applied to the selected word line is raised to Vpgm to program the target memory cell. In one embodiment, bias voltage applied to the unselected word lines remains at their last ramped-up level before t₁₄, e.g., at level 817. In another embodiment, the bias voltage applied to the unselected word lines may remain at Vpass, which is the pass-through voltage applied to all unselected word lines. In some embodiments, Vpass has the same value as Vpass_init. In other embodiments, they have different values.

FIG. 8B illustrates a similar mechanism to FIG. 8A which results in a boosted pillar potential for Pillar2 (see FIG. 5). In FIG. 8B, bias voltage applied to target bit line 504₂ is raised from 0V to a high voltage level 804 (which results in Pillar2 being floated) at time t₃, which is during the second staircase ramp-up. After Pillar2 is floated, its pillar potential Vch is being boosted up, e.g., at times t₄, t₆, etc., until it reaches a final boosted level 805 during the last staircase between time t₁₂ and t₁₄. Compared to FIG. 8A, since Pillar2 is floated later than Pillar1, the number of ramp-up staircases applied to Pillar2 is fewer than that of Pillar1, resulting in a lower final pillar potential (level 805) compared to Pillar1 (level 803).

FIG. 8C illustrates a similar process for Pillar6. In FIG. 8C, Pillar6 is floated during the last staircase at time t₁₃, resulting in the lowest boosted pillar potential (level 807) among the three pillars.

It should be noted that the number of staircases of word line bias voltages shown in FIGS. 8A-8C is for illustrative purposes only. Although seven staircases are shown here, in other embodiments, the number of steps in an ALP loop may vary and may not directly correspond to the number of programming levels in the memory array. It is also worth noting that the WL, BL and Vch waveforms shown in each of FIGS. 8A-8C represent one loop of an ALP operation. In some embodiments, the voltage increment between WL staircase steps (also referred to as the “delta voltage” or “staircase delta voltage”) remains the same across all loops. For example, in the five-loop ALP operation described in FIG. 6, the delta voltage can be consistent across all loops. However, in other embodiments, such as those described in FIG. 7, the delta voltage may be adjusted by the memory controller from loop to loop. In addition, the timing of bit line voltage toggle (shown the BL waveforms in FIGS. 8A-8C), e.g., time t₁ for Pillar1, may also be modified by the memory controller across loops.

In one embodiment, during the first loop, a smaller delta voltage of WL staircases (D₁) is applied. This results in a lower boost in pillar potentials in the first loop. In the second loop, a larger delta voltage (D₂) is applied (D₁<D₂), leading to a greater boost in pillar potentials. For the remaining loops, an even larger delta voltage (D₃) is applied (D₂<D₃), resulting in a graduate increase of pillar potential until the final loop.

In another embodiment, in the first loop, the first WL staircase (level 811) starts at an initial value (V₁) that is lower than Vpass_init. This results in the memory cells on a pillar not being fully turned on, causing the pillar to be not level-set by the target bit line. Thus, it results in a lower boost in the pillar potentials during the first loop. In the second loop, the first WL staircase starts at a relatively higher value (V₂), such as Vpass_init. In one embodiment, in the third loop and after, the first WL staircase starts at an even higher level (V₃), where V₁<V₂<V₃. In this way the pillar potentials are gradually boosted higher. In one embodiment, the delta voltages of the first or the second loops (D₁ or D₂) are lower than the delta voltage of the rest of the loops (D₃).

In another embodiment, instead of adjusting the initial staircase voltage or the delta voltages, the timing at which the bit line bias toggles from low to high (“time lapse”) can be adjusted across loops to achieve the same or similar effect. Referring to FIG. 8A as an example, t₁ during the first loop (L₁) may occur later than shown (but still before t₂). Since t₁ corresponds to the time when Pillar1 is floated, a later-floated pillar results in a lower boost in pillar potential in the first loop. Then, t₁ during the second loop (L₂) may occur earlier than L₁, and t₁ during the rest of the loops (L₃) may occur earlier than L₂ (but still after t₀), where L₃<L₂<L₁, so that the pillar potentials are boosted higher and higher.

In another embodiment, when programming Pillar1 in the first loop, instead of applying the word line and bit line bias voltages according to FIG. 8A, the waveforms in FIG. 8B are being applied. Therefore, instead of floating Pillar1 at time t₁, Pillar1 is floated at a later time t₃, resulting in a lower Vch boost in the first loop. For the subsequent loops, the original waveforms in FIG. 8A are used. More generally, the programming mechanism for a higher-level pillar is applied to a lower-level pillar during the first loop. After the first loop, the programming mechanism returns back to the original mechanism of the level being programmed. This process can be used when programming pillars L1 through L6 but does not apply to the highest-level pillar (e.g., L7 in a TLC array).

In some embodiments, the above-described mechanisms for adjusting word line or bit line waveforms can be combined to achieve a more desirable trend in the Vch waveform. For example, the delta voltages of WL staircases can be adjusted together with the timing of the bit line voltage toggling across loops to fine-tune the pillar potential boost.

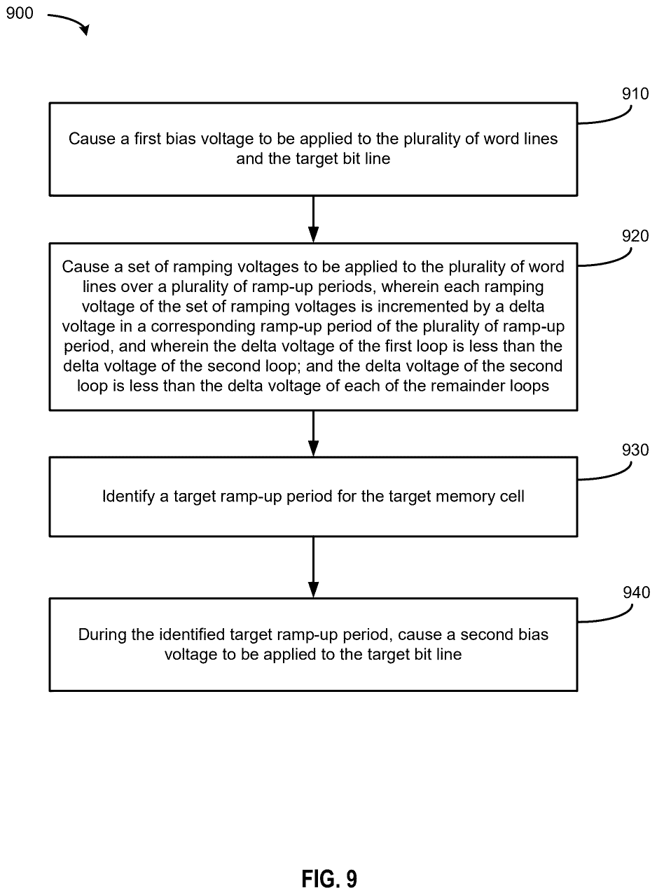

FIG. 9 is a flowchart illustrating a method 900 for performing all levels programming with loop dependent pillar boosting in accordance with examples as disclosed herein. Method 900 may be performed by a memory device, or memory controllers in a memory device, such as host system controller, a system controller 115, and/or a local controller 135. The memory device comprises an array of memory cells, a plurality of bit lines and a plurality of word lines coupled to the array of memory cells, and a memory controller. The plurality of bit lines comprises a target memory cell. The memory controller is configured to perform, during a programming operation, a plurality of operational loops to boost a pillar voltage of the target memory cell. The plurality of operational loops comprises a first loop, a second loop, and a set of remainder loops. Method 900 describes at least one loop of the plurality of operational loops the memory controller is configured to perform.

In some embodiments, method 900 can be implemented in the form of firmware that is stored in computer readable medium and executed by local controller 135 to cause the memory device 130 to perform the operations described herein.

At block 910, the memory controller causes a first bias voltage to be applied to the plurality of word lines and the target bit line. Referring back to FIG. 8A, the memory controller first applies 0V to the word lines (WL) and the target bit line (BL) at or before time t₀.

At block 920, the memory controller causes a set of ramping voltages to be applied to the plurality of word lines over a plurality of ramp-up periods, wherein each ramping voltage of the set of ramping voltages is incremented by a delta voltage in a corresponding ramp-up period of the plurality of ramp-up period, and wherein the delta voltage of the first loop is less than the delta voltage of the second loop; and the delta voltage of the second loop is less than the delta voltage of each of the remainder loops. Referring still to FIG. 8A, the memory controller applies a set of staircases (ramping voltages) to the word lines over a plurality of time periods from t₀ to t₁₄. Delta voltage is defined as the voltage step-up between each WL staircase, e.g., delta voltage 821 between the first and the second WL staircases. As previously described, in one embodiment, a smaller delta voltage (D₁) is applied in the first loop. In the second loop, a relatively larger delta voltage (D₂) is applied (D₁<D₂). In the remaining loops, a delta voltage (D₃) is applied where D₂<D₃.

At block 930, the memory controller identifies a target ramp-up period for the target memory cell. In one embodiment, the target ramp-up period is identified to correspond to the programming level of the target memory cell. Referring to FIGS. 8A-8C, the target ramp-up period during the first staircase (t₀-t₂) is identified for L1 pillars, the target ramp-up period during the second staircase (t₂-t₄) is identified for L2 pillars, and the target ramp-up period during the last staircase (t₁₂-t₁₄) is identified for L6 pillars.

At block 940, the memory controller, during the identified target ramp-up period, causes a second bias voltage to be applied to the target bit line. Referring still to FIGS. 8A-8C, the memory controller applies a high voltage value (e.g., Vcc) to the target bit line (BL) during the identified target ramp-up periods. For example, for L1 pillars, the memory controller raises the voltage applied to BL from 0V to Vcc at time t₁, which is during the identified target ramp-up period t₀-t₂. Similarly, for L2 pillars, BL is raised from 0V to Vcc at time t₃, which is during the identified target ramp-up period t₂-t₄. For L6 pillars, BL is raised at time t₁₃ during the identified target ramp-up period t₁₂-t₁₄.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells comprising a target memory cell;
a plurality of bit lines coupled to the array of memory cells, the plurality of bit lines comprising a target bit line coupled to the target memory cell,
a plurality of word lines coupled to the array of memory cells, and
a memory controller configured to perform, during a programming operation, a plurality of operational loops to boost a pillar voltage of the target memory cell, wherein in at least one loop of the plurality of operational loops the memory controller is configured to perform:
causing a first bias voltage to be applied to the plurality of word lines and the target bit line;
causing a set of ramping voltages to be applied to the plurality of word lines over a plurality of ramp-up periods, wherein each ramping voltage of the set of ramping voltages is incremented by a delta voltage in a corresponding ramp-up period of the plurality of ramp-up period;
identifying a target ramp-up period for the target memory cell; and
during the identified target ramp-up period, causing a second bias voltage to be applied to the target bit line.

2. The memory device of claim 1, wherein:
the plurality of operational loops comprise a first loop, a second loop, and a set of remainder loops;
the delta voltage of the first loop is less than the delta voltage of the second loop; and
the delta voltage of the second loop is less than the delta voltage of each of the remainder loops.

3. The memory device of claim 1, wherein:
the plurality of operational loops comprise a first loop, a second loop, and a set of remainder loops;
the set of ramping voltages comprise an initial pass voltage;
the initial pass voltage of the first loop is less than the initial pass voltage of the second loop; and
the delta voltage of the first loop or of the second loop is less than the delta voltage of each of the remainder loops.

4. The memory device of claim 1, wherein the second bias voltage is applied after a time lapse from when the first bias voltage is applied, and wherein
the plurality of operational loops comprise a first loop, a second loop, and a set of remainder loops;
the time lapse of the first loop is greater than the time lapse of the second loop; and
the time lapse of the second loop is greater than the time lapse of each of the remainder loops.

5. The memory device of claim 1, wherein the target ramp-up period is identified to correspond to a programming level of the target memory cell.

6. The memory device of claim 5, wherein the plurality of operational loops comprises a first loop and a set of remainder loops, and wherein the memory controller is further configured to perform, during the programming operation:
in the first loop, identifying the target ramp-up period to correspond to a programming level that is higher than the programming level of the target memory cell; and
in each loop of the set of remainder loops, identifying the target ramp-up period to correspond to the programming level of the target memory cell.

7. The memory device of claim 1, wherein the memory controller is further configured to perform, during the programming operation:
prior to causing the set of ramping voltages to be applied to the plurality of word lines over the plurality of ramp-up periods, causing a drain select gate coupled to the target bit line to be turned on.

8. The memory device of claim 1, wherein the memory controller is further configured to perform, during the programming operation:
during the target ramp-up period, causing a disconnection of a pillar associated with the target memory cell from a power supply and an electrical ground.

9. The memory device of claim 1, wherein the first bias voltage is ground voltage.

10. The memory device of claim 1, wherein the second bias voltage is a power supply voltage.

11. The memory device of claim 1, wherein the memory controller is further configured to perform, during the programming operation:
causing a programming voltage to be applied to a word line coupled to the target memory cell.

12. The memory device of claim 1, wherein the plurality of word lines comprises a set of unselected word lines coupled to other memory cells connected to the target bit line that are not the target memory cell, wherein the memory controller is configured to perform, during the programming operation:
after causing the set of ramping voltages to be applied to the plurality of word lines over the plurality of ramp-up periods, causing a pass voltage to be applied to the set of unselected word lines.

13. A method performed by a memory device, the memory device comprising an array of memory cells comprising a target memory cell, a plurality of bit lines coupled to the array of memory cells, the plurality of bit lines comprising a target bit line coupled to the target memory cell, and a plurality of word lines coupled to the array of memory cells, the method comprising a plurality of operational loops, at least one loop of the plurality of operational loops comprising:
causing a first bias voltage to be applied to the plurality of word lines and the target bit line;
causing a set of ramping voltages to be applied to the plurality of word lines over a plurality of ramp-up periods, wherein each ramping voltage of the set of ramping voltages is incremented by a delta voltage in a corresponding ramp-up period of the plurality of ramp-up period;
identifying a target ramp-up period for the target memory cell; and
during the identified target ramp-up period, causing a second bias voltage to be applied to the target bit line after a time lapse.

14. The method of claim 13, wherein:
the plurality of operational loops comprise a first loop, a second loop, and a set of remainder loops;
the delta voltage of the first loop is less than the delta voltage of the second loop; and
the delta voltage of the second loop is less than the delta voltage of each of the remainder loops.

15. The method of claim 13, wherein:
the plurality of operational loops comprise a first loop, a second loop, and a set of remainder loops;
the set of ramping voltages comprise an initial pass voltage;
the initial pass voltage of the first loop is less than the initial pass voltage of the second loop; and
the delta voltage of the first loop or of the second loop is less than the delta voltage of each of the remainder loops.

16. The method of claim 13, wherein the second bias voltage is applied after a time lapse from when the first bias voltage is applied, and wherein
the plurality of operational loops comprise a first loop, a second loop, and a set of remainder loops;
the time lapse of the first loop is greater than the time lapse of the second loop; and
the time lapse of the second loop is greater than the time lapse of each of the remainder loops.

17. The method of claim 13, wherein the target ramp-up period is identified to correspond to a programming level of the target memory cell.

18. The method of claim 17, wherein the plurality of operational loops comprises a first loop and a set of remainder loops, and wherein the memory controller is further configured to perform, during the programming operation:
in the first loop, identifying the target ramp-up period to correspond to a programming level that is higher than the programming level of the target memory cell; and
in each loop of the set of remainder loops, identifying the target ramp-up period to correspond to the programming level of the target memory cell.

19. A memory device comprising:
an input/output (I/O) circuit;
an array of memory cells comprising a target memory cell;
a plurality of bit lines coupled to the array of memory cells, the plurality of bit lines comprising a target bit line copuled to the target memory cell,
a plurality of word lines coupled to the array of memory cells, and
a memory controller configured to perform, during a programming operation, a plurality of operational loops to boost a pillar voltage of the target memory cell, wherein in at least one loop of the plurality of operational loops the memory controller is configured to perform:
causing a first bias voltage to be applied to the plurality of word lines and the target bit line;
causing a set of ramping voltages to be applied to the plurality of word lines over a plurality of ramp-up periods, wherein each ramping voltage of the set of ramping voltages is incremented by a delta voltage in a corresponding ramp-up period of the plurality of ramp-up period;
identifying a target ramp-up period for the target memory cell; and
during the identified target ramp-up period, causing a second bias voltage to be applied to the target bit line.

20. A system comprising:
a processor;
a first memory controller; and
an array of memory cells comprising a target memory cell;
a plurality of bit lines coupled to the array of memory cells, the plurality of bit lines comprising a target bit line copuled to the target memory cell,
a plurality of word lines coupled to the array of memory cells, and
a memory controller configured to perform, during a programming operation, a plurality of operational loops to boost a pillar voltage of the target memory cell, wherein in at least one loop of the plurality of operational loops the memory controller is configured to perform:
causing a first bias voltage to be applied to the plurality of word lines and the target bit line;
causing a set of ramping voltages to be applied to the plurality of word lines over a plurality of ramp-up periods, wherein each ramping voltage of the set of ramping voltages is incremented by a delta voltage in a corresponding ramp-up period of the plurality of ramp-up period;
identifying a target ramp-up period for the target memory cell; and
during the identified target ramp-up period, causing a second bias voltage to be applied to the target bit line.
